(19) United States
(12) Patent Application Publication
(10) Pub. No.: US 2022/0320435 A1
(43) Pub. Date: Oct. 6, 2022

(54) SYSTEMS, DEVICES, AND METHODS FOR DRYING MATERIAL DEPOSITED ON SUBSTRATES FOR ELECTRONIC DEVICE MANUFACTURING

(71) Applicant: Kateeva, Inc., Newark, CA (US)

(72) Inventors: Alexander Sou-Kang KO, Santa Clara, CA (US); Gregory LEWIS, Mountain View, CA (US); Song Jae LEE, Freemont, CA (US)

(73) Assignee: Kateeva, Inc., Newark, CA (US)

(21) Appl. No.: 17/597,774

(22) PCT Filed: Jul. 28, 2020
(86) PCT No.: PCT/US20/43798

§ 371 Date: Jan. 21, 2022

Related U.S. Application Data
(60) Provisional application No. 62/886,192, filed on Aug. 13, 2019.

(51) Int. Cl. H01L 51/00; H01L 51/56; H01L 27/32

(52) U.S. Cl. CPC H01L 51/0005; H01L 51/56; H01L 27/3262

(57) ABSTRACT

A system for drying material deposited on a substrate to form a solid, film layer includes a temperature-controlled substrate support apparatus to support a substrate; and an electromagnetic energy transmission system positioned to direct electromagnetic energy along a path incident on one or more locations on a surface of the substrate when supported by the substrate support apparatus. The electromagnetic energy transmission system is configured to transmit the electromagnetic energy in an amount sufficient to excite molecules of a liquid material deposited at the one or more locations of the substrate.

### TECHNICAL FIELD

Aspects of the present disclosure relate to systems, devices, and methods for drying liquid materials, such as ink, deposited on a substrate to form a thin film layer on the substrate. Such systems, devices, and methods can be used, for example, in the processing of substrates for the manufacture of electronic devices, including but not limited to, for example, electronic displays.

### INTRODUCTION

The section headings used herein are for organizational purposes only and are not to be construed as limiting the subject matter described in any way.

Electronic devices, such as optoelectronic devices, can be fabricated using various thin-film deposition and processing techniques in which one or more layers of materials are deposited onto a substrate, which can be a sacrificial substrate or be part of a final device. Examples of such devices include, but are not limited to, microchips, printed circuit boards, solar cells or panels, electronic displays (such as liquid crystal displays, organic light emitting diode displays, and quantum dot electroluminescent displays), or other devices. Applications for electronic display devices also can include general illumination, use as a backlight illumination source, or use as a pixel light source. One class of optoelectronic devices includes organic light emitting diode (OLED) devices, which can generate light using electroluminescent emissive organic materials such as small molecules, polymers, fluorescent, or phosphorescent materials.

The manufacture of OLEDs generally involves depositing one or more organic materials on a substrate to form a stack of thin films, and coupling the top and bottom of the stack of thin films to electrodes. The organic material is deposited in individual regions, sometimes referred to as “wells” that are bounded by bank structures, although any arrangement of individual regions can be used to form a pixelated display. Various techniques can be used to form the stack of thin films. In a thermal evaporation technique, organic material is vaporized in a relative vacuum environment and subsequently condensed onto the substrate. Another technique for forming the stack of thin films involves dissolution of the organic material into a solvent, deposition of the resulting solution on the substrate, and subsequent removal of the solvent by drying. Such a fluid transfer mechanism provides very thin film layers. An ink jet or thermal jet printing system may be used for deposition of organic material dissolved in a solvent. Other processes include organic vapor phase deposition for deposition of the organic material. In another drying technique, liquid materials can be dried by curing and causing polymerization of the deposited material.

Control over the material deposition and drying processes is important to the quality and lifetime of the resulting manufactured electronic device. For example, nonuniformities in a dried thin film layer can result in defects of the desired operation of the electronic device, including in visible defects (mura) that an observer may see when viewing an electronic display. Moreover, the increasing demand for electronic devices leads to the need to manufacture and process larger quantities and scales of substrates in a quality and efficient manner.

To achieve control over the drying process, it is desirable to subject the deposited liquid material to a controlled drying process as soon as practical after deposition on the substrate to avoid an uncontrolled evaporation of, for example, the solvent in an organic ink material or an uncontrolled polymerization of a curable material. Further, it is desired that the drying occurs quickly to achieve both uniformity in the produced thin film layer, as well as to achieve higher throughput in manufacturing. Moreover, some conventional drying techniques rely on the use of vacuum chambers, which can increase the cost and time associated with manufacturing electronic devices, in particular as the size of substrates being processed, and thus the chambers to accommodate such sizes, increases. Thus, the ability to achieve drying under conditions and in an environment that is relatively low in cost to maintain is desirable.

Accordingly, there exists a need for a drying technique suitable in the manufacturing of large-sized OLED display panels. Various embodiments of the drying system of the present disclosure can be used in the manufacturing of an OLED display panel to provide a panel with a high level of quality. The drying system of the embodiments of the present disclosure can be used to quickly dry inkjet droplets to provide a uniform and even film. Additionally, the drying system of the embodiments of the present disclosure can be used in atmospheric pressure, rather than in a vacuum chamber. For example, in some embodiments, the drying system of the present disclosure can be at a pressure ranging from about −5 mbar to about 5 mbar.

### SUMMARY

Both the foregoing general description and the following detailed description are exemplary and explanatory only and are not restrictive of the claims; rather the claims should be entitled to their full breadth of scope, including equivalents.

According to an exemplary embodiment, a system for drying material deposited on a substrate to form a solid, film layer includes a temperature-controlled substrate support apparatus to support a substrate; and an electromagnetic energy transmission system positioned to direct electromagnetic energy along a path incident on one or more locations on a surface of the substrate when supported by the substrate support apparatus. The electromagnetic energy transmission system is configured to transmit the electromagnetic energy in an amount sufficient to excite molecules of a liquid material deposited at the one or more locations of the substrate.

According to another exemplary embodiment, a method of drying a liquid material on a substrate to form a solid, film layer includes depositing a liquid material at one or more locations on a first surface of the substrate, and maintaining a second surface of the substrate opposite the first surface at a controlled temperature. The method further includes, while maintaining the second surface of the substrate at a controlled temperature, directing electromagnetic energy to be incident on the deposited liquid material at the one or more locations on the substrate, the electromagnetic energy being in an amount sufficient to evaporate liquid from the deposited liquid material at the one or more locations so as to form a solid film layer at the one or more locations of the substrate.

In yet another exemplary embodiment, a system for forming a film layer on a substrate comprises a temperature-controlled substrate support apparatus to support a substrate; a printing system comprising an inkjet printhead assembly for depositing liquid material at one or more locations on a surface of the substrate when supported by the substrate support apparatus; and a drying system comprising an electromagnetic energy transmission system positioned to direct electromagnetic energy along a path incident on the one or more locations on a surface of the substrate when supported by the substrate support apparatus. The electromagnetic energy transmission system is configured to transmit the electromagnetic energy in an amount sufficient to excite molecules of the liquid material deposited at the one or more locations of the substrate.

Additional objects, features, and/or other advantages will be set forth in part in the description which follows, and in part will be obvious from the description, or may be learned by practice of the present disclosure and/or claims. At least some of these objects and advantages may be realized and attained by the elements and combinations particularly pointed out in the appended claims.

Both the foregoing general description and the following detailed description are exemplary and explanatory only and are not restrictive of the claims; rather the claims should be entitled to their full breadth of scope, including equivalents.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more exemplary embodiments of the present teachings and together with the description explain certain principles and operation.

FIG. 1A schematically illustrates a system for drying ink deposited on a substrate to form a thin film layer manufacturing an electronic device in accordance with various exemplary embodiments of the present disclosure;

FIG. 1B schematically illustrates components of a drying system in accordance with exemplary embodiments of the present disclosure;

FIG. 2 schematically illustrates components of a drying system using photonic energy in accordance with an exemplary embodiment of the present disclosure;

FIG. 3 schematically illustrates components of a drying system using photonic energy in accordance with yet another exemplary embodiment of the present disclosure;

FIG. 4 schematically illustrates components of a drying system using photonic energy in accordance with an exemplary embodiment of the present disclosure;

FIG. 5 schematically illustrates components of a drying system using photonic energy in accordance with an exemplary embodiment of the present disclosure;

FIG. 6A is a diagrammatic perspective view of a drying system using photonic energy in accordance with an exemplary embodiment of the present disclosure;

FIG. 6B is a partial, close-up view of a portion of the drying system of FIG. 6A;

FIGS. 7A-7C schematically illustrate perspective views of components of a drying system using photonic energy in accordance with exemplary embodiments of the present disclosure;

FIG. 8 schematically illustrates a top view of an arrangement of components of a drying system using photonic energy in accordance with an exemplary embodiment of the present disclosure;

FIG. 9 schematically illustrates a top view of an arrangement of components of a drying system using photonic energy in accordance with another exemplary embodiment of the present disclosure;

FIG. 10 schematically illustrates a side view of components of a drying system using radio-frequency (RF) energy in accordance with yet another exemplary embodiment of the present disclosure;

FIG. 11 schematically illustrates a top view of an arrangement of components of a drying system using RF energy in accordance with an exemplary embodiment of the present disclosure;

FIG. 12 schematically illustrates a top view of an arrangement of components of a drying system using RF energy in accordance with another exemplary embodiment of the present disclosure; and

FIG. 13. schematically illustrates a drying system integrated within a printing system enclosure according to an exemplary embodiment of the present disclosure.

FIG. 14 schematically illustrates a coating system comprising a printing system enclosure operably coupled to a drying system enclosure in accordance with an exemplary embodiment of the present disclosure.

### DETAILED DESCRIPTION

This description and the accompanying drawings that illustrate aspects and embodiments should not be taken as limiting. The claims define the scope of protection, including equivalents. Various mechanical, compositional, structural, electrical, and operational changes may be made without departing from the scope of this description and the claims. In some instances, well-known circuits, structures, and techniques have not been shown or described in detail in order not to obscure the embodiments and disclosed inventions.

Further, this description's terminology is not intended to limit the scope of the claims. For example, spatially relative terms—such as “y-axis direction,” “x-axis direction,” “z-axis direction,” “above,” “below,” and the like—may be used to describe one element's or feature's relationship to another element or feature as illustrated in the figures. These spatially relative terms are intended to encompass different directions (e.g., in a Cartesian coordinate system), positions (i.e., locations) and orientations (i.e., rotational placements) of a device in use or operation in addition to the position and orientation shown in the figures. For example, if a device in the figures is turned over, elements described as “below” or “beneath” other elements or features would then be “above” or “over” the other elements or features. Thus, the exemplary term “below” can encompass both positions and orientations of above and below. A device may be otherwise oriented (rotated 90 degrees or at other orientations) and the spatially relative descriptors used herein interpreted accordingly. Likewise, descriptions of movement along and around various axes include various special device positions and orientations. In addition, the singular forms “a,” “an,” and “the” are intended to include the plural forms as well, unless the context indicates otherwise. And, the terms “comprises,” “comprising,” “includes,” and the like specify the presence of stated features, steps, operations, elements, and/or components but do not preclude the presence or addition of one or more other features, steps, operations, elements, components, and/or groups. Components described as coupled may be electrically or mechanically directly coupled, or they may be indirectly coupled via one or more intermediate components. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

Elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment.

Various exemplary embodiments described herein include systems, methods, and devices for drying liquid material deposited on a substrate during the manufacture of any of a variety of electronic devices, including but not limited to, for example, OLED display devices. Various exemplary embodiments contemplate the industrial scale manufacture of such electronic devices, and thus envision application in a variety of manufacturing applications, ranging from relatively small generational size substrates up to large-sized substrate formats, for example, a Gen 8.5 to a Gen 11. A Gen 8.5 substrate has dimensions of about 220 cm×250 cm and a Gen 11 substrate has dimensions of about 300 cm×332 cm.

Various exemplary embodiments in accordance with the present disclosure contemplate the use of drying techniques to dry deposited liquid material (e.g., organic ink material) to remove solvent and form a thin film layer on the substrate whereby the drying can be done relatively rapidly and in a pressure environment that does not require a vacuum, such as, for example, in an atmospheric pressure environment.

In accordance with various exemplary embodiments, drying systems can be located in an enclosure in which deposition of material onto the substrate occurs, such as, for example, in an enclosure housing a coating system (e.g., an inkjet printing system). Incorporating the drying system into the enclosure of the coating system can allow for drying to occur one portion of the substrate at a time and relatively immediately after deposition occurs, such as for example, in a pixel-by-pixel manner or rows or groups of pixels at a time. Alternatively, the present disclosure contemplates embodiments in which drying systems are a stand-alone module, which can receive a substrate for drying that is transported from a separate enclosure of a coating system.

Various exemplary embodiments further contemplate drying techniques that rely on the application of energy to be absorbed directly to the material to be dried, as opposed to applying heat through the entirety of the substrate by conduction for example, and/or using convection over the surface of the substrate on which the material to be dried is deposited. As such, the drying techniques disclosed herein may be applied directly to the intended portion of the deposited material, thus achieving relatively efficient and rapid drying. This can result in uniform film layers and higher throughput. Additionally, various embodiments of disclosed drying techniques allow the energy applied to the material to be tuned in intensity and duration of exposure, thus further enhancing uniformity in the produced film layers. Such localized and customized drying permits drying of ink in a pixel to be concentrated in a center, for example, to compensate for edge drying effects that can result in non-uniformity within a pixel itself. Thus, drying techniques according to various exemplary embodiments can promote both in-pixel film thickness uniformity as well as uniformity across an entire display or multiple pixels of a display.

While various disclosed embodiments dry by evaporation of solvent from a liquid material, the present disclosure also contemplates drying by curing to cause polymerization of a liquid material.

Various embodiments of the present disclosure further contemplate drying systems that can provide flexibility in the ability to achieve multiple patterns of drying at discrete locations on a surface of a substrate, and in control over the arrangement and motion of the various components (e.g., substrate and/or components of the electromagnetic energy transmission system). For large-scale manufacturing, providing such flexibility can promote efficiency in the drying process (and thus overall manufacturing process), increase throughput, and allow for accommodation of various size substrates using a single drying system.

Various embodiments of the present disclosure further contemplate drying systems that use a temperature-controlled support apparatus to support and provide heating and/or cooling of the substrate, for example through conduction and/or convection. Such a temperature-controlled support apparatus can provide additional heating or cooling, further increasing uniformity in the produced film layers. In some embodiments, the substrate support apparatus can be controlled to be held at a temperature to provide cooling of the substrate relative to ambient temperature. Providing such cooling in combination with the focused application of electromagnetic energy to deposited material may be desirable to protect against damage to underlying features on a substrate, such as, for example, electrical features, etc. that are laid down under the deposited liquid material to be dried to a solid layer.

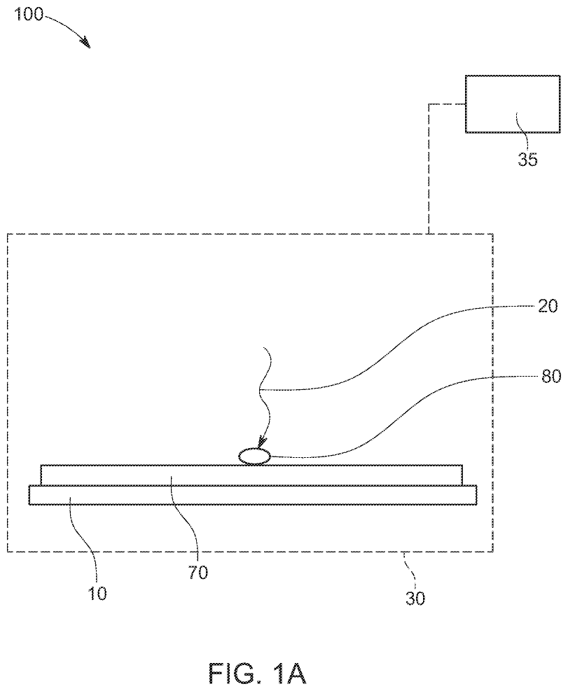

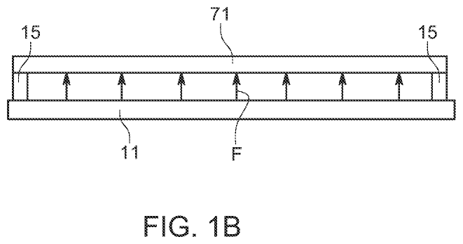

An exemplary embodiment of a drying system in accordance with the present disclosure is illustrated in FIG. 1A. Drying system 100 comprises an electromagnetic energy transmission system that can generate and direct electromagnetic energy 20 to dry a droplet 80 of liquid material deposited on a substrate 70 to produce a thin solid film on substrate 70. Electromagnetic energy 20 may dry droplet 80 by either causing solvent in the liquid material to evaporate or by causing the liquid material to polymerize (i.e., curing the liquid material). Electromagnetic energy 20 may can be transmitted along a path to be incident on a surface of the substrate 70, for example, in one or more discrete locations (such as in pixels) where material (e.g., droplets 80) to be dried has been deposited on the substrate 70. In some embodiments, electromagnetic energy 20 is relatively focused and is a directed photonic energy path incident on a localized area of the substrate, such as a well, or other discrete location at which the droplet is deposited, e.g., to form pixels or subpixels of a display. In some embodiments, the discrete locations have a width ranging from about 15 μm to about 100 μm and a length ranging from about 32 μm to about 250 μm. For example, the discrete locations have a size ranging from about 60 μm×175 μm, in some embodiments. Alternatively, though not depicted in FIG. 1A, electromagnetic energy can be incident over larger areas of the substrate, to be incident on multiple droplets at a time and/or on large coated areas of a substrate, which will be described further below with respect to additional embodiments.

Droplet 80 may be a liquid organic material, such as an ink droplet. It is within the scope of this disclosure that droplet 80 may be a single droplet or may be a plurality of individual droplets that have coalesced together to form a single volume. As such, use of the term droplet is for convenience and is intended to encompass relatively minute discrete volumes of material to be dried to form a layer, such as to define a pixel or subpixel format of a substrate in the context of an electronic display. A droplet may have a volume ranging from, for example, about 3 pL to about 30 pL. Furthermore, as used herein, droplet may be a liquid film deposited on a substrate, such as in spray coating or slot nozzle coating deposition process.

In one embodiment, electromagnetic energy 20 can be an energy sufficient to be absorbed by the droplet 80 to excite molecules in the droplet 80 and result in heating and drying the droplet 80, for example, via evaporation of solvent from the liquid material, leaving a solid film layer behind. This heating mechanism thus provides a direct, rapid, and efficient heating of the droplet 80, which can dry the droplet relatively quickly to provide a relatively uniform and even film layer on substrate 70. In some embodiments, electromagnetic energy 20 can be an energy sufficient to excite polar molecules in the droplet 80 and result in heating and drying the droplet 80. Electromagnetic energy 20 may be applied to only droplet 80 and not to a portion of substrate 70 surrounding the droplet 80. The energy applied to droplet 80 may result in a thermal gradient in droplet 80 such that a top portion of droplet 80 (relatively further from substrate support apparatus 10) has a higher thermal temperature than a bottom portion of droplet 80 (relatively closer to substrate support apparatus 10). The thermal gradient produced within droplet 80 can result in uniform drying of droplet 80 from electromagnetic energy 20.

In various exemplary embodiments, electromagnetic energy 20 is photonic energy or radio frequency (RF) energy. When photonic energy is used, the wavelengths may be in a range of from about 500 nm to about 5000 nm. In some examples, the wavelengths may be in the range from about 1000 nm to about 3000 nm, and in some embodiments in the range from about 1500 nm to about 3000 nm. The wavelengths may be selected based upon the properties of the ink solvent in droplet 80, and the wavelengths may be varied based upon the optical absorbance of ink solvent in droplet 80. When RF energy is used, the frequencies may be within the ISM (industrial, scientific, and medical) band, for example, 13.56 MHz, 27.12 MHz, or 40.68 MHz. However, these frequencies are exemplary and non-limiting; as discussed above, other wavelengths and frequencies may be used to achieve polymerization of curable liquid materials.

As shown in FIG. 1A, drying system 100 further comprises a substrate support apparatus 10 to support the substrate 70 during the drying process. The substrate support apparatus 10 can have a variety of configurations, such as a plate or chuck, including a vacuum chuck, a floatation table configured to support the substrate via floatation (e.g., a gas bearing in an exemplary embodiment), or any other suitable substrate support apparatus with which those having ordinary skill in the art of substrate processing for electronic device manufacture would be familiar. The substrate support apparatus can hold the substrate 70 in a fixed position or may be configured to move (convey), for example via a motion system discussed further below, the substrate 70, such as in an X- or Y-direction defined in the plane parallel to the surface of the substrate on which the droplet 80 lies. In an exemplary embodiment, the drying system 100 can include plurality drying zones and the substrate 70 can be moved throughout the zones, as further described below with reference to other figures and embodiments. Moreover, substrate 70 can be inserted and removed from drying system 100 using a substrate loading and unloading system (not shown). Depending on the configuration, this can be accomplished with a mechanical conveyor, a substrate floatation table, or a substrate transfer robot with end effector, or a combination thereof.

In some embodiments, the substrate support apparatus 10 is temperature-controlled and is configured to apply heat and/or cooling to substrate 70. The heating and/or cooling helps to control the evaporation or curing rate of droplet 80 on substrate 70, thus increasing the uniformity of the resulting film. The applied heating and/or cooling may be uniform across the entire substrate 70, or may be conducted in multiple controlled zones of the substrate support apparatus. For example, a first zone of substrate 70 may be controlled to a different temperature than a second zone of substrate 70 by applying differing temperature control to differing portions of the substrate support apparatus 10 supporting the substrate 70. Substrate support apparatus 10 may heat and/or cool substrate 70 using conduction, for example, a liquid or a gas medium circulating within the substrate support apparatus and in contact with the substrate 70. Alternatively, the substrate support apparatus 10 can be a thermoelectric device using Peltier temperature control.

While some embodiments contemplate heating and/or cooling the substrate through conduction with the substrate in contact with the substrate support apparatus, other embodiments contemplate the substrate being lifted above the substrate support apparatus (e.g., via floatation table with or without lift pins), with heating and/or cooling occurring by liquid or gas flow and convection at least under the substrate. In exemplary embodiments, the substrate can be held in place on the substrate support apparatus, such as by vacuum with the substrate support apparatus being a vacuum chuck and/or by clamps or other mechanical gripping mechanisms.

In some embodiments, the substrate support apparatus 10 cools the substrate while the electromagnetic energy is directed and absorbed by the droplet on the substrate, thus resulting in drying or curing of the droplet. Cooling the substrate may prevent the damaging underlying features on the substrate, such as electrical components or additional layers, which can be caused if those features are subject to too high a temperature, such as by absorption of the electromagnetic energy. The substrate support apparatus may cool the substrate by maintaining a temperature on the supporting side of the substrate of, for example, from about 0° C. to about 30° C., or for example, from about 10° C. to about 30° C., or for example, from about 15° C. to about 30° C. However, it is contemplated that the temperature to which the substrate is cooled may be varied based upon the underlying features on the substrate and the material of the substrate.

FIG. 1B shows an exemplary embodiment of a substrate support apparatus 11 that has lift pins (which can be retractable) to support the substrate 71 while temperature-controlled fluid F (e.g., gas or liquid) is ejected from the substrate support apparatus 11 to heat and/or cool the substrate 71. Lift pins 15 can be located around a periphery of the substrate 71, but such location is not exclusive and other locations are contemplated as well. Substrate support apparatus 10, 11 may also move substrate 70, 71 in one or more different positions, as discussed further below.

If substrate support apparatus is a floatation table, it is envisioned that various types of floatation tables can be used, including pressure-only and/or pressure/vacuum combinations to produce a fluidic spring effect and tighter control over the fly height of the substrate during floatation. In the latter case, it may be possible to not use lift pins to support the substrate. Those having ordinary skill in the art would have familiarity with various types of floatation tables that could be utilized, with appropriate heating or cooling of the gas flow to achieve controlled heating/cooling of the substrate.

Referring again to FIG. 1A, drying system 100 may optionally include an enclosure 30 shown in dotted lines in FIG. 1A. The enclosure 30 can be sealable to be able to maintain a controlled processing environment, including control over any of temperature, pressure, gas content, etc., within the enclosure 30. In various exemplary embodiments, it is contemplated that the drying systems, such as drying system 100, operates within atmospheric pressure and as such the environment within the enclosure 30 can be at or near atmospheric pressure. In various exemplary embodiments, the enclosure 30 of drying system 100 can be operably coupled with various components that provide a source of gas to the interior (such as air, nitrogen, any of the noble gases, or combinations thereof), gas circulation and filtration system, a gas purification system, a thermal regulation system and/or a solvent trap apparatus and/or a solvent exhaust system to remove evaporated particulates. Such components are generally and schematically depicted as 35 in FIG. 1A.

The drying system 100 may be part of a coating system such that the drying and coating systems are in the same enclosure. In other embodiments, the drying system 100 may be separate from a coating system enclosure, such as two separate enclosures, and configured to receive a substrate that has been processed in the coating system. For example, drying system 100 may be coupled to the coating system such that after a substrate receives a deposition of liquid coating material, the substrate is moved from the enclosure of a coating system to an enclosure of the drying system 100. The drying system enclosure can be directly coupled to the coating system enclosure. Alternatively, a transfer module or holding module can be disposed between the coating and drying system enclosures. In other embodiments, a drying system can be co-located with a coating system, and drying can occur in situ with the coating (deposition of liquid material) of the substrate.

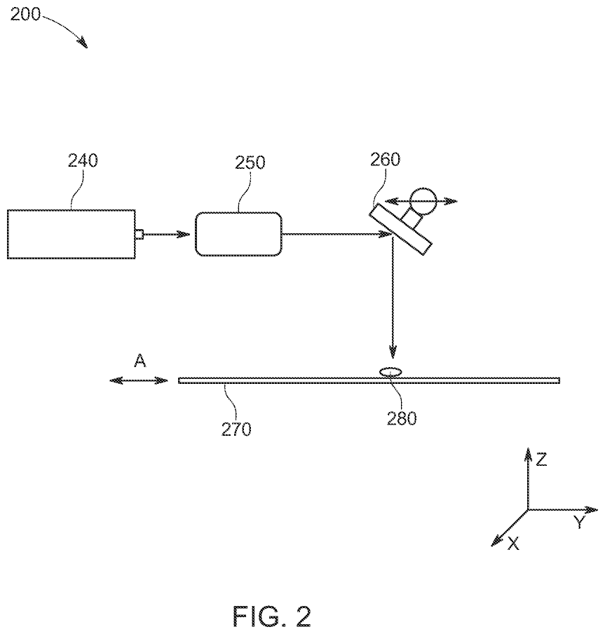

In accordance with various embodiments of the present disclosure, a drying system can use photonic energy as the electromagnetic energy in the drying process. FIGS. 2-9 schematically illustrate various embodiments of drying systems that use photonic energy in accordance with the present disclosure. With reference to FIG. 2, one exemplary embodiment of a drying system 200 utilizing photon energy as the electromagnetic energy to dry the liquid material deposited on substrate 270 is illustrated. In this embodiment, drying system 200 comprises a photon energy transmission system that directs photon energy derived from a light source to be incident on a droplet 280 deposited on a surface of the substrate 270. As shown, the photon energy transmission system of FIG. 2 includes a light source 240 that is sufficient to emit incident light onto droplet 280 to excite the molecules in droplet 280 to generate heat, as described above. The light source 240 can be chosen from a variety of light sources, such as a laser, LED, or incandescent source and has a wavelength ranging from about 500 nm to about 5000 nm. In some examples, the wavelength ranges from about 1000 nm to about 3000 nm, and in some embodiments from about 1500 nm to about 3000 nm. These ranges are nonlimiting and the wavelength can be selected based upon the properties of the ink solvent in droplet 80 including the optical absorbance properties of the ink solvent in droplet 280. The light source 240 can be combined with other optical devices and/or itself can be tunable to provide differing wavelengths as desired based on particular applications, such as properties of the material of the droplet being dried. The power of the light source 240 may also be tunable and configured to produce a modulated or pulsed output.

The drying system 200 further includes an optics assembly 250 and one or more reflective members 260 positioned to redirect and/or focus the light to impinge upon the droplet 280. Light source 240 can be positioned laterally to a side of the optics assembly 250, such that both the light source 240 and optics assembly 250 transmit respective light paths generally parallel to the surface of the substrate 270. As shown in FIG. 2, optics assembly 250 can include one or more components to focus and modify the light transmitted from light source 240 so that the proper amount of energy is applied to droplet 280. Additionally, the components of optics assembly 250 may be used to properly position the transmitted light directly onto droplet 280. The components of optics assembly 250 may include, for example, one or more optical filters, lens, prisms, and/or mirrors, as those skilled in the art would be familiar with. Optics assembly 250 may also include one or more optical sensors to measure the characteristics of light entering and being transmitted from optics assembly 250. Optics assembly 250 may also include one or more components that shape the beam of the transmitted light, such as, for example, a lens or a polarizer.

Drying system 200 further comprises a reflecting member 260 to redirect the photonic energy from the light source, and optionally through the optics assembly 250, to be incident on the droplet 280. In other words, the reflecting member is arranged and configured to turn the light path of the photonic energy to be in a direction substantially normal to the surface of the substrate 270 and incident on the droplet 280 to be dried. It is also contemplated that drying module 200 may not include optics assembly 250. When included, optics assembly 250 may be positioned between light source 240 and reflective members 260, as shown in FIG. 2. However, it is also contemplated that optics assembly 250 may be positioned anywhere along the path of the transmitted photonic energy, including downstream of the reflective member 260 (with the upstream to downstream direction being from the light source to the substrate). Optics assembly 250 may also include more than one assembly, for example, two or three assemblies. Additionally, light source 240 and optics assembly 250 may be combined into one component, and/or optics assembly 250 and reflective members 260 may be combined into one component. Those having ordinary skill in the art will appreciate various combinations and arrangements of the light source, optics assembly, and reflective member to modify and transmit photonic energy in a manner to achieve drying as desired based on a particular application.

Reflective member 260 may be one or more rotatable mirrors that direct the transmitted light directly onto droplet 280. In an exemplary embodiment, reflective member 260 can be a moving/translating mirror or an electromagnetically pivoting mirror, for example. The position of the reflective member 260 may be monitored, recorded, and/or controlled automatically to reposition the photonic energy path to various locations as desired during a drying process of a substrate.

Each of light source 240, optics assembly 250, and/or reflective members 260 may be coupled with software to display, analyze, and record the visual representation of the transmitted light. Additionally, each of these components may be coupled with a controller for automatically controlling the components based on sensed information concerning a position of the substrate, the type of material to be dried, and numerous other factors that those of ordinary skill in the art would understand.

In the illustration of FIG. 2, the transmitted photonic energy is incident onto a single droplet 280. In an embodiment, the incident energy may be sufficient to encompass the entirety of the droplet 280. In another embodiment, it may be that the incident energy only encompasses a portion of the droplet 280 at a time, in which case the photonic energy path may be moved relative to the droplet to be incident on various portions of the droplet 280 sequentially. For example, the photonic energy first can be directed to a left half of the droplet and then to a right half of the droplet, or vice versa. When focused on a single droplet, for example, the incident energy can be directed so as to not be incident on areas of the substrate surrounding the droplet 280 and without material to be dried deposited in those areas.

In an exemplary embodiment, the drying system 200 can be configured to move the photon energy transmitted relative to the substrate surface to provide localized drying at different locations on the surface of the substrate. This can be achieved by moving the incident energy path, the substrate (shown by arrow A for example in FIG. 2), or both.

A motion system may move one or more components of the drying system 200. The motion system can move the components relative to each other in order to direct and move the incident photonic energy to various locations relative to the substrate surface. It is also contemplated that substrate 270 can be moved relative to the path of incident electromagnetic energy. The motion system can include substrate support apparatus 10, as discussed above with reference to FIGS. 1A and 1B to move substrate 270.

As shown in the embodiment of FIG. 2, a motion system can be configured to move the substrate 270 relative to the incident photonic energy path, as shown by arrows A. Substrate 270 thus can move in a horizontal plane along a Y-direction. In such a configuration, the reflective member 260 may be configured to orient and move the incident photonic energy path in the X-direction such that the entirety of the surface of the substrate can eventually have the photonic energy incident thereon. Those having ordinary skill in the art will appreciate a variety of motions to permit movement of the substrate and the incident photonic energy relative to each other.

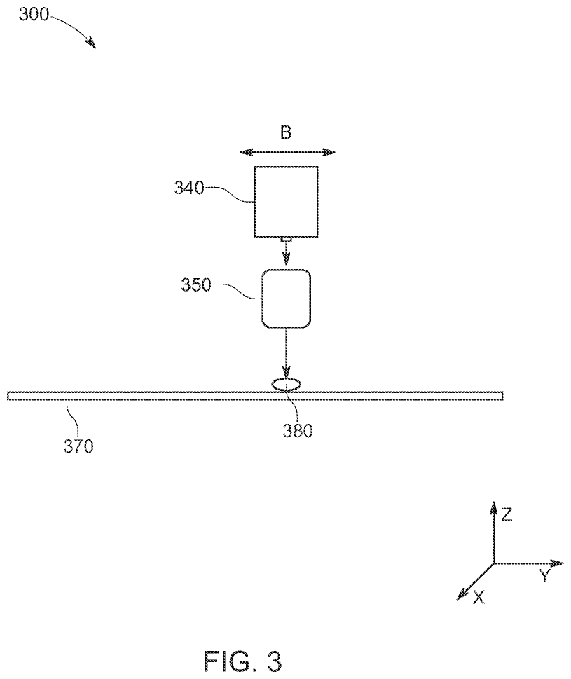

FIG. 3 illustrates an embodiment of a drying system 300 in which the photonic transmission system comprises a light source and optics assembly that are arranged to transmit incident light in a direction normal to a surface of a substrate. In such an arrangement, a reflective member to redirect the photonic energy may not be needed. In FIG. 3, light source 340 is positioned above the surface of the substrate 370 to direct a photonic energy path in a direction substantially normal to the surface of the substrate 370 as shown. Optics assembly 350 can be positioned to intercept the transmitted energy path from the light source 340 and further direct the incident photonic energy in a direction normal to the surface of the substrate, so as to be incident on a droplet 380 for example. It is also contemplated in the embodiment of FIG. 3 that the photonic energy transmission system is configured to move in translation to move the incident photonic energy path relative to substrate 370. As shown by arrows B, light source 340 and optics assembly 350 can move in a horizontal plane along the Y-axis direction of substrate 370 to properly position the transmitted light relative to droplet 380. A motion system (not shown) can be operably coupled to allow such movement. Although FIG. 3 shows the arrows B indicating movement of the light source 340 and optics assembly 350 in the Y-direction, those having ordinary skill in the art would understand that the light source 340 and optics assembly 350 could move in the X-direction, alternatively or in addition to the Y-direction. Further, as described with respect to the embodiment of FIG. 2, the substrate 370 also can move in one or both of the X- and Y-directions.

The embodiments of FIGS. 2 and 3 depict a relatively focused and directed photonic energy path incident on a localized area of the substrate, such as a well, or other discrete location at which the droplet is deposited, e.g., to form pixels or subpixels of a display. In some embodiments, the discrete locations have a width ranging from about 15 μm to about 100 μm and a length ranging from about 32 μm to about 250 μm. In one embodiment, the discrete locations have a size of about 60 μm×175 μm. However, a drying system in accordance with various exemplary embodiments can have photonic energy incident on multiple droplets simultaneously, either through multiple discrete paths or a broader, diffuse path that covers more area of the surface of the substrate.

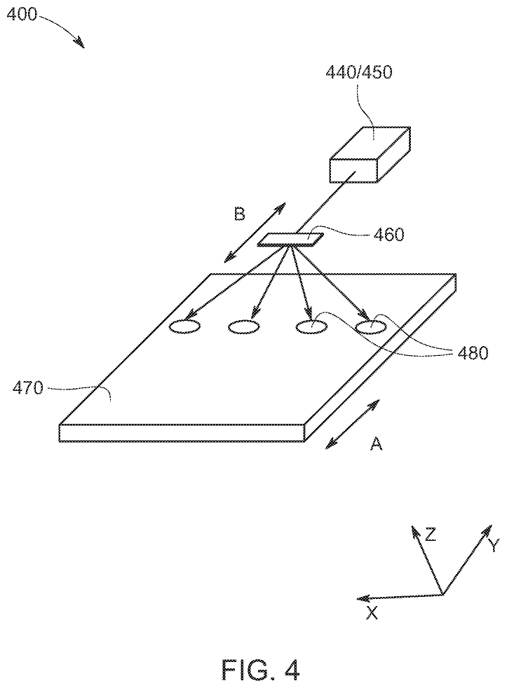

FIG. 4 depicts an embodiment of a drying system 400 in which the photonic energy transmission system is configured to direct photonic energy from a light source onto a plurality of discrete locations (e.g., droplets) at a time. As shown in FIG. 4, a reflective member 460 can direct the transmitted energy from light source 440 onto a plurality of droplets 480 simultaneously. Thus, the drying system of FIG. 4 can dry a plurality of droplets simultaneously. To achieve the ability to direct the photonic energy to multiple droplets at once, for example, arranged generally in a line (row) across the substrate 470, the reflective member 460 can be a scanning moving/translating mirror.

As depicted by arrows A and B in the embodiment of FIG. 4, either or both of the reflective member 460 and the substrate 470 can move, for example, along the Y-direction so as to be able to cover the entirety of the substrate surface, to dry the rows of droplets (extending in the X-direction) arrayed thereon in the embodiment of FIG. 4. In the embodiment of FIG. 4, reflective member 460 moves in the direction of arrows B with light source 440 (and optionally optics assembly 450 that may be included as part of light source 440) to direct the transmitted light onto each droplet 480. In addition to or instead of translating in the Y-direction, reflective member 460 can be tilted and/or rotated to redirect the incident photonic energy to different regions of the surface of substrate 470, for example to direct the photonic energy to different rows of droplets 480. Further, as discussed above, if the incident photonic energy paths from the reflective member 460 do not cover the entirety of the material to be dried (e.g., the entirety of a droplet) then the reflective member 460 can be tilted and/or translated to direct the light to different portions of a droplet to perform the drying. In the embodiment of FIG. 4, light source 440 and optics assembly 450 optionally may be combined into one component, as discussed above. However, it is also contemplated that optics assembly 450 may be a separate component from light source 440, as shown in FIG. 2, for example.

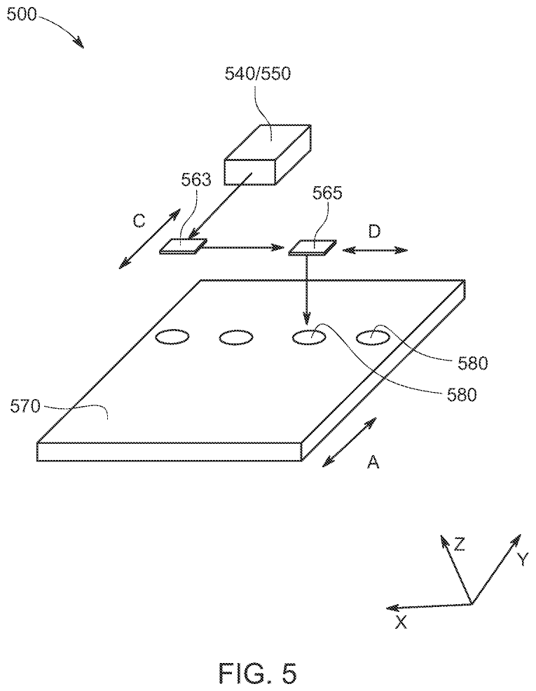

FIG. 5 shows another exemplary embodiment of a drying system 500 using a photonic energy transmission system. The embodiment of FIG. 5 includes two reflective members 563, 565, which as above can be scanning and/or moving/translating mirrors, for example. First mirror 563 and/or second mirror 565 may move such that the transmitted photonic energy is directed individually onto each droplet 580 on a surface of the substrate 570. In one configuration, in order to provide drying to individual discrete locations (e.g., droplets in an array) over the entirety of the surface of the substrate 570, the substrate 570 can move in the Y-direction, as shown by arrows A and reflective member 565 can move in the X-direction, as shown by arrows D. The light source/optics assembly 540, 550 and reflective member 563 can remain stationary, with movement of reflective member 565 and the substrate 570 being able to provide the X-Y relative movement of the incident photonic energy and surface of the substrate needed to cover the entire surface of the substrate 570. In another configuration, the substrate 570 can remain stationary, and reflective member 563 can move in the Y-direction, as shown by arrows C, and reflective member 565 can move in the X-direction, as shown by arrows D. Such a configuration also allows for the X-Y relative movement of the incident photonic energy and the surface of the substrate to provide drying to all desired locations on a surface of the substrate. In yet other configurations, the substrate 570, the reflective member 563, and the reflective member 565 can all move to achieve the ability to direct the incident photonic energy at all desired locations of the surface of the substrate.

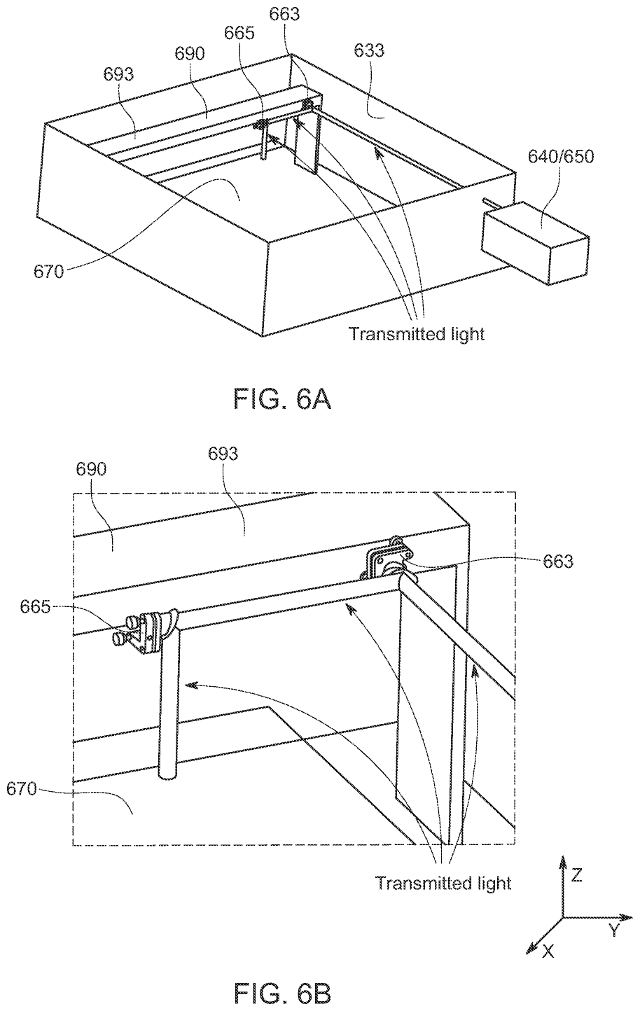

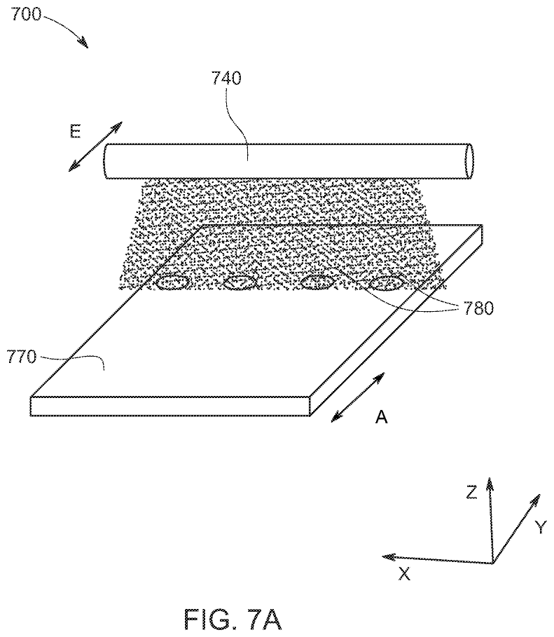

A variety of motion systems may be used to control movement of the various components of the dryings systems of the exemplary embodiments herein. For example, in various exemplary embodiments, a gantry system, including, for example, a split-axis gantry system, can be used to move one or more of the components of the photonic energy transmission systems. FIGS. 6A and 6B show one exemplary embodiment of gantry system 690 that can be used to provide the motion of first and second reflective members 663, 665, such as moving/translating mirrors, for a photonic energy transmission system having similar components and motions to that described with reference to FIG. 5. In FIGS. 6A and 6B, gantry system 690 is shown within an enclosure 633 (the ceiling being removed to show the interior) sized to receive a substrate for drying. The enclosure 633 can be a stand-alone drying module or can house a printing system to provide a combined printing and drying module.

FIGS. 6A and 6B show that light source 640 (and optionally optics assembly 650) is positioned exterior of enclosure 633. The transmitted light is emitted through enclosure 633 and then reflected by reflective members 663, 665, similar to the embodiment of FIG. 5 described above. It is also contemplated that light source 640 (and optionally optics member 650) may be positioned interior of enclosure 633. Positioning light source 640 (and optionally optics member 650) in the interior of enclosure 633 may provide increased protection to these components. However, positioning light source 640 (and optionally optics member 650) outside of enclosure 633 may allow enclosure 633 to have a smaller profile and may reduce the amount of heat generated inside enclosure 633, which may provide for less maintenance to the various components within the enclosure. Maintenance may also be simplified when various optical components are placed outside of the enclosure, particularly if the enclosure is required to be brought to certain conditions, such as an inert gas environment.

Gantry system 690 comprises a rail 693 that is disposed above substrate 670 and extends across the width of the substrate 670. Reflective member 665 can be configured to move in the X-direction across the rail 693. Additionally, gantry system 690 may be configured to move the first and second reflective members 663, 665 in the Y-axis direction of substrate 670, as discussed above, for example with reference to FIG. 5

FIGS. 2-6B show the light source, optics assembly, reflecting members, and/or substrate as moving along the Y-axis direction of the substrate. However, it is also contemplated that the movement of any of these components may be in the X-axis direction of the substrate. Additionally, or alternatively, the distance between the light source, reflecting members, and/or substrate can be altered by moving the various components in a Z-axis direction. For example, the light source and reflecting members may be moved toward and away a from a top surface of the substrate.

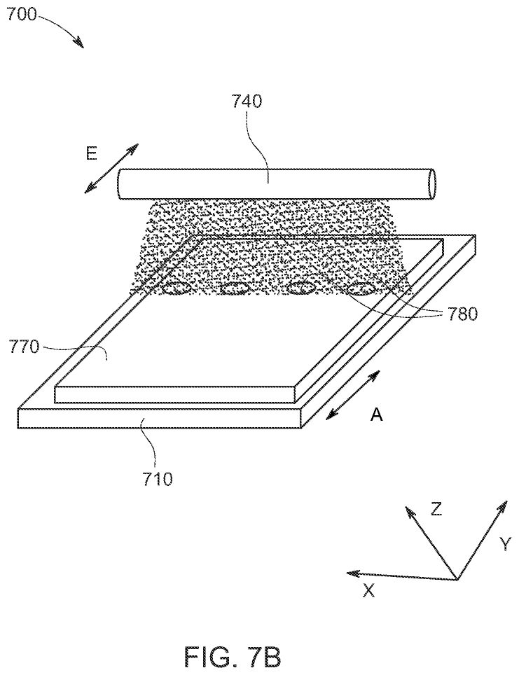

In some embodiments, a drying system comprising a photonic energy transmission system in accordance with the present disclosure can use a light source that is one or more broad spectrum diffuse light sources to produce the incident photonic energy over a larger area of a substrate surface, as opposed to the focused incident paths described above with reference to FIGS. 2-6B. As shown in FIG. 7A, a photonic energy transmission system 700 comprises a light source that is a broad spectrum diffuse light source, such as a lamp 740. The lamp 740 is configured to direct light across a width of substrate 770 to, for example, dry deposited ink at various locations across the substrate, such as a plurality of droplets 780 in a row across the substrate 770. Although FIG. 7 only shows one broad spectrum diffuse light sources, it is also within the scope of the disclosure that the light source could be a group of broad spectra diffuse light sources. Light source 740 may be, for example, one or more LEDs, IR emitters, Xenon lamps, plasma lamps, or gas-discharge lamps.

As shown in FIG. 7A, light source 740 and substrate 770 can move relative to each other, for example by employing one or more motion systems. For example, in an embodiment where one or more light sources 740 provides incident photonic energy across an X-direction of the substrate, the one or more light sources 740 and/or the substrate 770 can be configured to move relative to each other in the Y-direction, as shown by arrows E and A, respectively.

As shown in FIG. 7A, light source 740 can be configured to illuminate only a portion of substrate 770 at a time as it moves in the direction of arrows E. For example, FIG. 7A shows light source 740 illuminating a single row of droplets 780 at a time. However, it is also contemplated that light source 740 may be sized and tailored for substrate 770 so that incident photonic energy from the light source 740 covers multiple rows or other arrays of droplets, including covering the entire top surface area of substrate 770.

As discussed above, light source 740 may be substantially the same length and width of substrate 770. It is also within the scope of the disclosure that light source 740 may be proportionally sized relative to substrate 770. For example, light source 740 may be one-half, one-third, or one-fourth the size of substrate 770. Additionally, light source 740 may be configured to emit the illumination light to cover a row of droplets, or a plurality of droplets in various groupings such as, for example, a square, circular, triangular, or elliptical shape.

As shown in FIG. 7B, the transmitted photonic energy incident onto droplets 780 from light source 740 may be used in conjunction with a substrate support apparatus 710 to move the substrate, for example along the Y-direction. Although using a substrate support apparatus to move the substrate in a Y-axis direction may be useful when the incident photonic energy extends across or is able to travel across the X-direction of the substrate, those having ordinary skill in the art would appreciate that a substrate support apparatus in various embodiments could move in the X-direction or in both the X- and Y-directions. In an exemplary embodiment, the substrate support apparatus 710 can be a temperature-controlled substrate support apparatus, as discussed above with reference to FIGS. 1A and 1B, to provide heating and/or cooling to substrate 770. Such an arrangement may provide better control over the evaporation of droplets 780 on substrate 770 so as to enhance the uniformity of the resulting thin film. Although not shown in the embodiments of FIGS. 2-6, 8, and 9, those having ordinary skill in the art would appreciate that any of those embodiments also can utilize a substrate support apparatus, which can be moveable to move the substrate, for example in an X- and/or Y-direction, and/or can be temperature-controlled, such as those discussed above with reference to FIGS. 1A and 1B.

Various embodiments of the disclosed drying system may use a light source coupled with a mask to direct the incident light directly onto the droplets. As shown in FIG. 7C, the light transmitted from light source 740 may be directed through mask 790 before it is incident on substrate 770. As discussed above, light source 740 may be a broad spectrum diffuse light source, such as a lamp. Mask 790 may be disposed between light source 740 and substrate 770, and mask 790 may include one or more holes 795 through which the incident passes so that it is directed onto droplets 780 on substrate 770. Thus, a portion of the incident light from light source 740 may be blocked by mask 790 so that the blocked light does not reach substrate 770. By blocking a portion of the incident light, mask 790 may help to localize the incident light onto the droplets 780. In some embodiments, holes 795 may correspond to and match the pattern of droplets 780. For example, holes 795 may be a single row of holes that are aligned with a single row of droplets 780. However, it also contemplated that holes 795 may be any pattern of holes that are aligned with the same pattern of droplets 780. Thus, mask 790 may be used with an aligning apparatus (not shown) to properly position the mask. Holes 795 may be sized so that they are larger, smaller, or the same size as droplets 780.

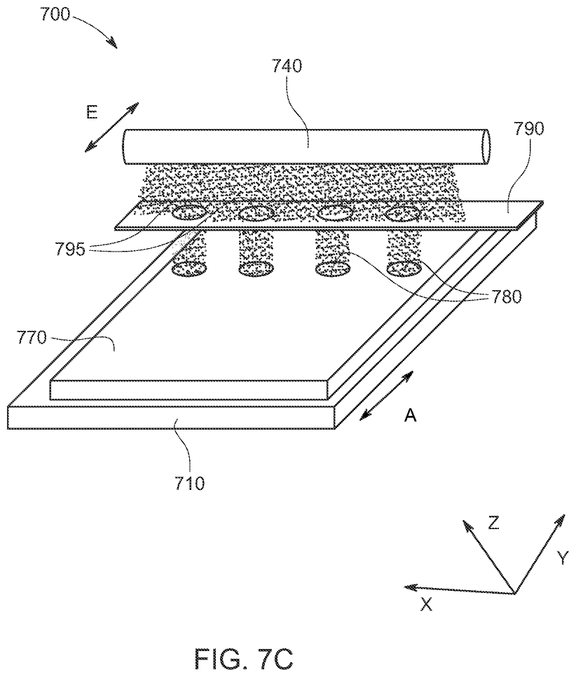

In various embodiments, it is also contemplated that the photonic energy transmission systems can be configured to provide incident light to cover multiple rows of droplets at a time along the X-direction. FIG. 8 schematically depicts a top perspective view of substrate 870 in an embodiment of a photonic energy transmission system 800 in which a plurality of light sources 840 can be used to provide a plurality of incident energy paths in bands (e.g., each to cover a row of droplets) across the substrate 870. In FIG. 8, three such lights sources 840 are shown, although any number can be used. It is contemplated that the photonic energy transmission system having light sources can have a configuration like the lamps 740 of the embodiment of FIG. 7A. The photonic energy transmission systems can be configured such that each of the light sources 840, and thus the incident energy bands, moves relative to the substrate 870 in the Y-direction shown by arrows E. They may be configured to move together or separately from each other relative to substrate 870. As also discussed above, substrate 870 may be configured to move in the Y-direction shown by arrows A.

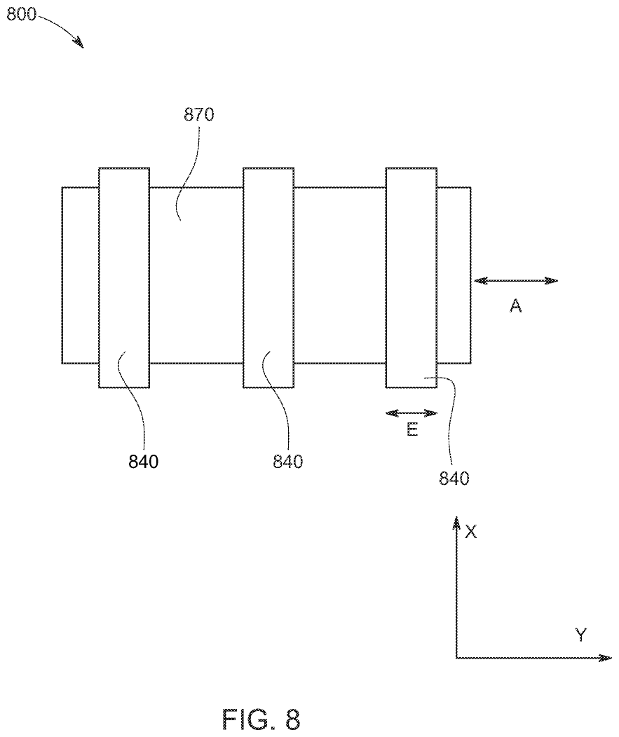

In another embodiment of a photonic energy transmission system 900, shown in FIG. 9, light sources 940 can be positioned at an angle to, rather than parallel to, the X-direction. For example, light sources 940 may be positioned about 5 degrees to about 15 degrees relative to a Y-axis of substrate 970. Light sources 940 may each be positioned at the same angle or at different angles relative to the Y-axis of substrate 970. As discussed above, light sources 940 and/or substrate 970 may move relative to each other so that the incident photonic energy eventually is provided over the entirety of the surface of the substrate 970 (e.g., to cover all droplets deposited on the surface). Angling the incident energy as illustrated in FIG. 9 can help to minimize visible artifacts from potential non-uniformities in drying that may be more prominent if such nonuniformities were to occur in aligned rows and/or columns of an array of pixels/subpixels on the surface of the substrate. Although FIG. 9 shows a plurality of angled light sources 940, it is also within the scope of the disclosure that a photonic energy transmission system that has only one light source also can use an angle light source.

The multiple light sources 840, 940 in the embodiments of FIGS. 8 and 9 may be used with multiple masks. For example, each light source 840, 940 may be coupled with a mask to direct the incident light onto each droplet.

In the embodiments of FIG. 7A-9, the wavelength of the light source(s) may be selected based on the properties of the ink solvent in droplet 80 including the absorbance characteristics of the droplet, as discussed above. In exemplary embodiments, the light source(s) of FIGS. 7A-9 may emit light in a wavelength range from about 500 nm to about 5000 nm. In some examples, the wavelength may range from about 1000 nm to about 3000 nm, and in some embodiments the wavelength may range from about 1500 nm to about 3000 nm. The light source(s) may each be a single elongated light source that spans the width of the substrate. Alternatively, each light source may comprise plural light sources positioned to spread light effectively across the entire width of the substrate. It is also contemplated that the light source(s) may provide more illumination light in one or more focalized regions corresponding to where the droplets are deposited. It is also contemplated that the light source(s) may each provide areas of differing wavelength, intensity, frequency modulation, and/or duration of illumination light.

FIGS. 7A-9 show the light source(s) as moving along the Y-direction. However, it is also contemplated that the movement may be in the X-direction, and additionally the light sources may be arranged to be parallel to the Y-direction in FIGS. 7A-8. Additionally or alternatively, the distance between the light source(s) and the substrate can be altered by moving the various components in a Z-axis direction. For example, the light source(s) may be moved toward and away from a top surface of the substrate.

In the embodiments of FIGS. 2-9, the wavelength, duration, frequency modulation, and intensity of the incident photonic energy may be selected based on a variety of factors. For example, the wavelength, duration, frequency modulation, and intensity can be selected based on the properties of the material that is being dried, such as the volume of the droplets, the absorption/excitation wavelengths material, etc. For example, the incident light may have a wavelength of 1550 nm, an intensity of 35 mW, and an exposure time of about 35 minutes.

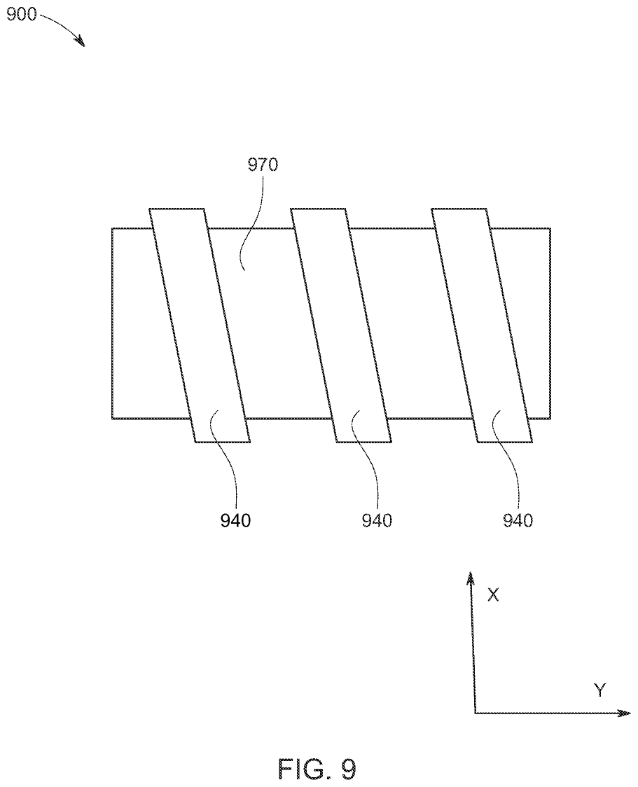

FIGS. 2-9 show embodiments in which photon energy is used to dry the droplets to produce a thin and uniform film on the substrate. However, it also contemplated that other types of electromagnetic energy can be used to provide the incident energy needed to directly excite droplets deposited on the surface of the substrate during electronic device manufacture. For example, as shown in FIG. 10, radio frequency (RF) energy can be used to dry the droplets and produce the thin and uniform film layers. In FIG. 10, drying system 1000 includes an RF energy transmission system to dry the droplets on substrate 1070. As in the embodiments relying on photonic incident energy to perform the drying process, the RF energy incident upon the material to be dried (e.g., one or more droplets) excites molecules within the material such that the molecules generate heat to dry the material.

The drying system 1000 includes an RF generator 1040 coupled with first and second electrodes 1043, 1045 that are spaced apart from one another. When the RF generator 1040 is powered to create an electrical potential between the electrodes 1043, 1045, an RF energy field 1065 is created between the electrodes. Energy field 1065 can be manipulated based upon the distance between electrodes 1043, 1045. Thus, electrodes 1043, 1045 may each move in a Z-axis direction relative to the other electrodes. The electrodes 1043, 1045 may be moved independently from each other such that one of the electrodes can be closer to the substrate if desired.

Either before or after the formation of energy field 1065, at least a portion of substrate 1070 is moved between first and second electrodes 1043, 1045. Substrate 1070 may be moved relative to first and second electrodes 1043, 1045 via substrate support apparatus 10, 11, 710 (e.g., mechanical conveyor, gas cushion, floatation table, and/or chuck), as discussed above. It is also contemplated that first and second electrodes 1043, 1045 can move relative to substrate 1070. Energy field 1065 is incident on droplets on the surface of the substrate disposed between the electrodes 1043, 1045, thereby exciting the molecules of the material of the droplets to heat and dry the droplets to form a thin film layer. The RF energy field 1065 generally will span a region of the surface of the substrate and, thus, act on a plurality of droplets simultaneously.

First and second electrodes 1043, 1045 may be sized such that the entirety of substrate 1070 is disposed between the electrodes and within energy field 1065 at the same point in time. Alternatively, as shown in FIG. 10, only a portion, which is less than the entirety of substrate 1070, can be disposed between the electrodes and within energy field 1065 at the same time.

As discussed above, substrate 1070 and first and second electrodes 1043, 1045 can move relative to each other in the direction as shown by arrows F. Thus, substrate 1070 and energy field 1065 can move relative to each other. The movement of substrate 1070, first and second electrodes 1043, 1045, and energy field 1065 may be in the Y-direction of substrate 1070, as shown by arrows F in FIG. 10. Such movement allows all portions of substrate 1070 to be moved into energy field 1065.

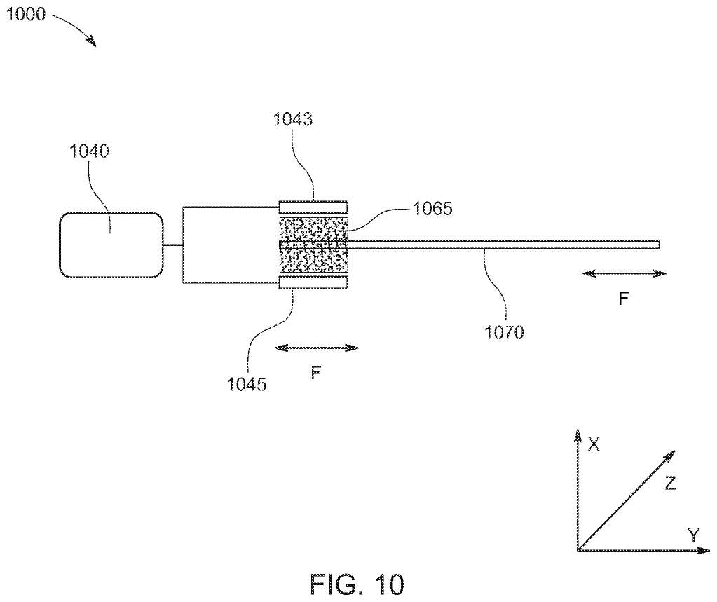

As in the embodiment of FIGS. 8 and 9, it is contemplated that multiple RF energy fields can be positioned along the substrate in drying system 1100 to more effectively dry multiple portions of the substrate at a time. FIG. 11 shows a top perspective view of substrate 1170 in an embodiment in which a plurality of electrodes are disposed along substrate 1170. FIG. 11 shows three first electrodes 1143 disposed above substrate. Although the second electrodes are not shown, this embodiment would also include three corresponding second electrodes to produce three energy fields. Although three energy fields would be produced in FIG. 11, it is also contemplated that any number of electrode pairs could be utilized. The arrangement of the electrode pairs is such that they are parallel to each other and the X-direction in the embodiment of FIG. 11.

In the embodiment of FIG. 11, the first and second electrodes may be configured to move in a direction shown by arrows F, as discussed above. The electrode pairs may be configured to move together or separate from other electrode pairs relative to substrate 1170. As also discussed above, substrate 1170 may be configured to move relative to the electrodes in a direction shown by arrows F.

It is also contemplated in the embodiment of FIG. 11 that first electrodes 1143 are all paired with a common second electrode to produce the different energy fields. Alternatively, multiple second electrodes may be paired with a common first electrode to produce the different energy fields.

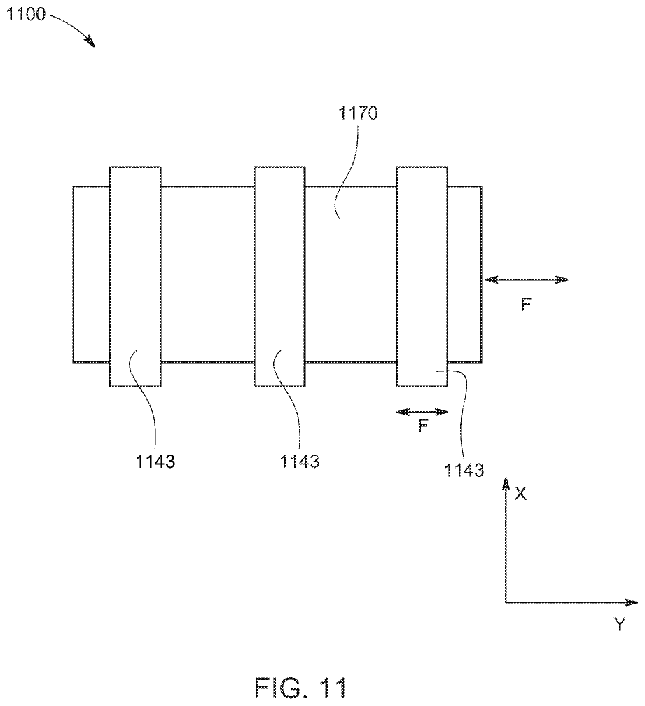

In some embodiments, instead of being positioned parallel to each other and the X-direction, the electrodes can be positioned at an angle and not parallel to the X-direction as shown in drying system 12000, similar to the embodiment of FIG. 9 described above, in order to minimize the impact of visual artifacts that may result from nonuniformities in the dried layers that may otherwise be aligned along rows or columns of an array of pixels/subpixels on the surface of the substrate. As discussed above, the electrodes and/or substrate 1270 may move so that every droplet on substrate 1270 may be disposed within the energy field. Although FIG. 12 shows a plurality of angled electrodes, it is also within the scope of the disclosure that only a single angled electrode pair is used.

In the embodiments of FIGS. 10-12, RF energy field 1065 may be a single energy field that spans the width of the substrate. Alternatively, one or more RF generators and electrode pairs can be positioned to effectively provide one or more RF energy fields across the entire width of the substrate. It is also contemplated that the RF energy field may be applied to one or more focalized regions corresponding to where the droplets are deposited. It is also contemplated that a plurality of RF generators may be used, each producing an RF energy field with a different intensity and/or duration.

In the embodiments of FIG. 10-12, the RF energy generator may produce an RF energy field incident upon the surface of the substrate that has a frequency within the ISM band, for example, but not limited to 13.56 MHz, 27.12 MHz, or 40.68 MHz. The RF generator may be controllable to alter the frequency, and thus strength of the RF energy field incident upon the substrate surface. Thus, in various embodiments, the RF energy field may be tuned as desired to achieve drying based on the particular application, such as the properties of the material being dried, volume of material being dried, etc. In the embodiments of FIGS. 10-12, the duration and intensity of the generated RF energy field may be selected based upon a variety of factors. For example, the duration and intensity can be selected based on the properties of the material that is being dried, such as the volume of the droplets, the absorption/excitation wavelengths material, etc.

FIGS. 10-12 show the electrodes as moving along the Y-axis of the substrate. However, it is also contemplated that the movement of any of these components may be in the X-axis direction of the substrate. Additionally, or alternatively, the distance between the substrate and each electrode can be altered by moving the various components in a Z-axis direction. For example, the electrodes may be moved toward and away from the substrate, as discussed above. Such may be used to provide the optimum spacing between the electrodes to generate the RF energy field.

The generated RF energy fields of the embodiments of FIG. 10-12 may be used with a substrate support apparatus (not shown) according to any of the embodiments described above in order to provide support, movement of the substrate, and/or temperature control (heating and/or cooling) of the substrate.

Drying systems in accordance with various embodiments may be used under pressure conditions other than vacuum pressure, such as, for example, atmospheric pressure conditions. The ability to perform relatively rapid and uniform drying to form thin film layers can simplify the drying process in electronic device manufacturing. For example, drying systems in accordance with exemplary embodiments of the present disclosure can be integrated within a coating system enclosure, such as, for example, a printing system enclosure, such that the drying can be performed in situ as material is deposited onto the substrate without the need to transport the substrate to a separate chamber, for example, to provide vacuum pressure conditions. In an embodiment in which the drying system is integrated within a printing system enclosure, one of ordinary skill in the art would appreciate that various components of the printing system, such as a substrate support apparatus and/or a bridge to provide X-direction motion of a printhead assembly, may be used in conjunction with the drying system components to achieve relative motions of the substrate and the incident energy transmission path(s) to achieve drying over the various desired locations on the substrate surface.

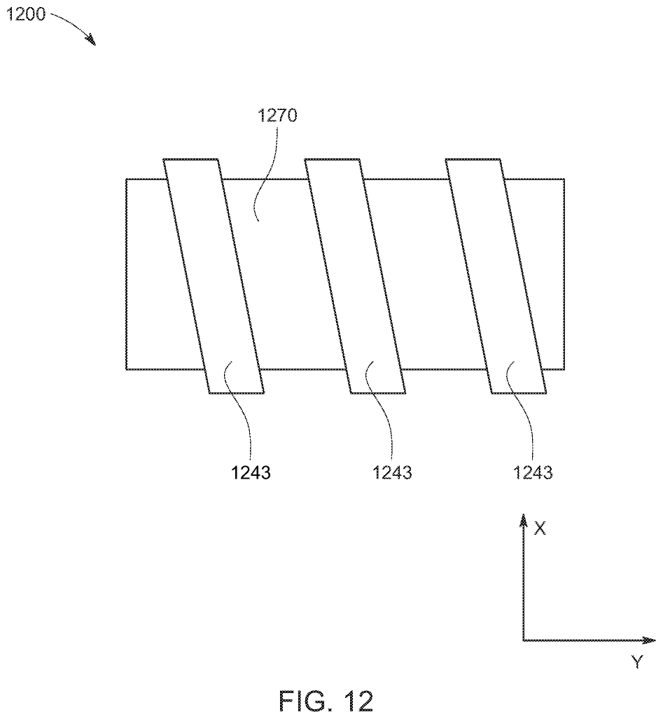

FIG. 13 schematically depicts an embodiment wherein a drying system 1300 is integrated within a printing system enclosure 1330, a substrate support apparatus 1310, and a printing system bridge 1320 supporting an inkjet printhead assembly 1325. Such an arrangement allows a substrate 1370 to be supported by the substrate support apparatus 1310 while the printhead assembly 1325 moves along the bridge 1320 to deposit material (e.g., organic material ink droplets) at discrete locations and/or in a pattern on the substrate 1370. The substrate support apparatus can be any of the substrate support apparatus structures described above with reference to various embodiments. A motion system can control movement of the substrate and the inkjet printhead assembly relative to one another, as those having ordinary skill in the art would be familiar with. While the drying system 1300 is depicted as a general component in FIG. 13, those having ordinary skill in the art would appreciate that the system 1300 can comprise any of the components described herein of the embodiments of the disclosed drying systems. For example, printing system bridge 1320 may comprise at least a portion of gantry system 690. In some embodiments, printing system bridge 1320 may comprise reflective member 665 and printhead assembly 1325 may comprise reflective member 663. Further, some components described herein may be positioned outside the enclosure, but nonetheless operably coupled to the enclosure such that the drying process can occur within the printing system enclosure.

In an exemplary embodiment, it is contemplated that the drying system 1300 can be controlled in concert with the printhead assembly 1325 to direct the incident drying electromagnetic energy to locations of the substrate at which ink has been deposited by the printhead assembly. Thus, the printing system may, for example, deposit the material at one or more discrete locations on the substrate and/or in a desired pattern on the substrate in situ with the operation of the disclosed drying system. For example, in an exemplary embodiment, the drying system 1300 can be controlled to dry deposited material at locations of the substrate within about 30 seconds to about 3 minutes after deposition.

The interior of the enclosure housing drying system 1300 and printing system enclosure 1330 may be maintained at a controlled processing environment. In some embodiments, the controlled processing environment is at ambient pressure.

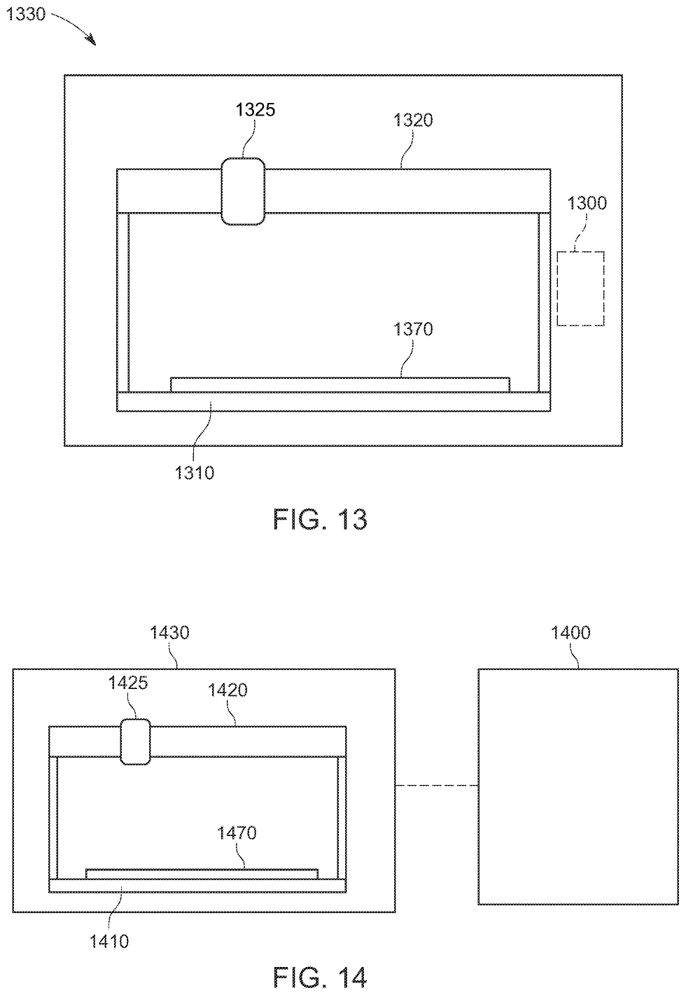

In another exemplary embodiment, a drying system may be provided as a separate enclosure from a coating system enclosure but accessible thereto either by direct transport of a substrate between the two enclosures or using a transfer or holding chamber deposited between the two enclosures. In other embodiments, it is contemplated that the drying system is a module that can be combined in various locations and workflows with an overall modular coating system to provide flexibility in how the drying system is operably coupled to other modules of the coating system. In each of these embodiments, the drying system and coating system may both be maintained in a controlled processing environment at ambient pressure. FIG. 14 illustrates an exemplary embodiment in which a coating system comprising a printing system enclosure 1430, similar to that of 1330 in FIG. 13 with like parts being labeled as 1400 series rather than 1300 series, is operably coupled to a drying system 1400 such that a substrate can be transported between the two. In such an embodiment, a portion of the substrate can be printed in stages and moved to the drying system enclosure to dry and then moved back to the printing system enclosure 1430. For example, in an exemplary embodiment for creating a red, green, blue pixel display, the red material may be deposited first in the desired locations on the substrate and then the substrate can be moved to the drying system to dry the deposited red material, followed by the green and then the blue material. Of course, those having ordinary skill in the art would appreciate that this is just one example of the order of material deposition and drying and other orders and techniques would be obvious to one having ordinary skill in the art based on the present disclosure.

It is within the scope of this disclosure that the above-discussed embodiments of the drying systems, including electromagnetic energy transmission systems, can be combined. Thus, the features of each of these embodiments may be combined with features of the other embodiments. The different embodiments are not mutually exclusive and, instead, are combinable as would be apparent to one having ordinary skill in the art.

Various exemplary embodiments of the drying systems discussed throughout the disclosure may provide quick drying of the droplets on the substrate to produce thin and uniform film layers on the substrate. Thus, the droplets may be dried substantially immediately after they are deposited on the substrate. Additionally, each droplet may be evenly dried by the disclosed drying system so that, for example, a first portion of the droplet is not fully dried before a second portion of the droplet is fully dried. Instead, the disclosed drying system uniformly dries the entire droplet.

Drying systems according to the various embodiments also can allow for easy drying of large-sized substrates to produce a relatively large display panel. The drying systems allow the droplets on the substrate to be accessed, and thus dried, from a variety of positions, even when the substrate is of a large size. Thus, the disclosed drying systems according to various embodiments can provide an economic and efficient way to dry droplets on substrates of various sizes.

Electronic devices manufactured using embodiments of drying techniques and systems of the present disclosure may include, for example and without limitation, electronic displays or display components, printed circuit boards, or other electronic components. Such components may be used in, for example, handheld electronic devices, televisions or computer displays, or other electronic devices incorporating display technologies.

It is to be understood that the examples and embodiments set forth herein are non-limiting, and modifications to structure, dimensions, materials, and methodologies may be made without departing from the scope of the present teachings. Other embodiments in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A system for drying material deposited on a substrate to form a film layer, the system comprising:
a temperature-controlled substrate support apparatus to support a substrate; and
an electromagnetic energy transmission system positioned to direct electromagnetic energy along a path incident on one or more locations at a surface of the substrate when supported by the substrate support apparatus,
wherein the electromagnetic energy transmission system is configured to transmit the electromagnetic energy in an amount sufficient to excite molecules of a liquid material deposited at the one or more locations of the substrate.

2. The system of claim 1, wherein the temperature-controlled substrate support apparatus is maintained at a temperature to cool a substrate supported by the temperature-controlled substrate support apparatus.

3. The system according to claim 2, wherein the electromagnetic energy transmission system is positioned to direct the electromagnetic energy on or more locations on a surface of the substrate facing away from the substrate support apparatus.

4. The system according to claim 3, wherein the one or more locations each have a width ranging from about 15 μm to about 100 μm and a length ranging from about 32 μm to about 250 μm.

5. The system according to claim 2, wherein the substrate support apparatus is configured to impart relative motion between the substrate supported by the substrate support apparatus and the path of the electromagnetic energy from the electromagnetic energy transmission system.

6. The system according to claim 5, wherein the electromagnetic energy transmission system is configured to move the path of electromagnetic energy relative to the substrate.

7. The system of claim 2, further comprising one or more reflective members positioned along the path of electromagnetic energy.

8. The system of claim 7, wherein the one or more reflective members comprises a first reflective member and a second reflective member, wherein:
the first reflective member and the second reflective member are moveable relative to the substrate in a Y-axis direction of the substrate, and
the second reflective member is moveable relative to the substrate and to the first reflective member in an X-axis direction of the substrate.

9. The system of claim 1, wherein the electromagnetic energy has a wavelength ranging from about 500 nm to about 5000 nm.

10. The system of claim 9, wherein the electromagnetic energy has a wavelength ranging from about 1500 nm to about 3000 nm.

11. The system of claim 1, further comprising a mask configured to block at least a portion of the incident electromagnetic energy from reaching the substrate.

12. The system of claim 1, wherein the electromagnetic energy transmission system comprises a plurality of light sources to produce the incident electromagnetic energy, the plurality of light sources being in a linear array across the substrate.

13. The system of claim 12, wherein the plurality of light sources are disposed at a non-perpendicular angle relative to edges of the substrate.

14. The system of claim 1, wherein the electromagnetic energy transmission system is configured to direct the electromagnetic energy using a radio frequency energy field.

15. The system of claim 14, further comprising a pair of electrodes to produce the radio frequency energy field.

16. The system of claim 15, wherein the pair of electrodes is a plurality of pairs of electrodes at differing locations along the substrate.

17. A method of drying a liquid material on a substrate to form a solid, film layer, the method comprising:
depositing a liquid material at one or more locations on a first surface of the substrate;
maintaining a second surface of the substrate opposite the first surface at a controlled temperature; and
while maintaining the second surface of the substrate at a controlled temperature, directing electromagnetic energy to be incident on the deposited liquid material at the one or more locations on the substrate, the electromagnetic energy being in an amount sufficient to evaporate liquid from the deposited liquid material at the one or more locations so as to form a solid film layer at the one or more locations of the substrate.

18. The method of claim 17, wherein the one or more locations each have a width ranging from about 15 μm to about 100 μm and a length ranging from about 32 μm to about 250 μm.

19. The method of claim 17, wherein maintaining the second surface of the substrate at the controlled temperature comprises cooling the second surface of the substrate relative to ambient temperature of an environment surrounding the substrate.

20. The method of claim 17, wherein the electromagnetic energy is incident light having wavelength ranging from about 500 nm to about 5000 nm.

21. The method of claim 20, wherein the electromagnetic energy is incident light having a wavelength ranging from about 1500 nm to about 3000 nm.

22. The method of claim 17, wherein the electromagnetic energy is from a radio frequency energy field.

23. The method of claim 17, further comprising moving at least one of the substrate and the incident electromagnetic energy relative to each other to direct the incident electromagnetic energy to differing regions of the second surface of the substrate.

24. The method of claim 17, wherein:
the liquid material is deposited in a discrete volume at the one or more locations, and
the electromagnetic energy is incident upon the discrete volume at each of the one or more locations in an amount sufficient to excite molecules of the liquid material.

25. The method of claim 17, wherein the electromagnetic energy is incident upon a plurality of locations at a time.

26. The method of claim 17, wherein the electromagnetic energy is incident upon a single location at a time, and the method further comprises moving at least one of the substrate and the electromagnetic energy relative to each other to direct the electromagnetic energy to plural locations at which the liquid material is deposited.

27. The method of claim 17, wherein the liquid material is an organic light-emissive liquid material.

28. A system for forming a film layer on a substrate, the system comprising:
a temperature-controlled substrate support apparatus to support a substrate;
a printing system comprising an inkjet printhead assembly for depositing liquid material at one or more locations on a surface of the substrate when supported by the substrate support apparatus; and
a drying system comprising an electromagnetic energy transmission system positioned to direct electromagnetic energy along a path incident on the one or more locations on a surface of the substrate when supported by the substrate support apparatus,
wherein the electromagnetic energy transmission system is configured to transmit the electromagnetic energy in an amount sufficient to excite molecules of the liquid material deposited at the one or more locations of the substrate.

29. The system of claim 28, wherein the temperature-controlled substrate support apparatus is maintained at a temperature to cool a substrate supported by the temperature-controlled substrate support apparatus.

30. The system according to claim 29, wherein the electromagnetic energy transmission system is positioned to direct the electromagnetic energy on or more locations on a surface of the substrate facing away from the substrate support apparatus.

31. The system according to claim 30, wherein the one or more locations each have a width ranging from about 15 μm to about 100 μm and a length ranging from about 32 μm to about 250 μm.

32. The system according to claim 28, wherein the drying system is housed within an enclosure of the printing system.

33. The system according to claim 32, wherein the enclosure of the printing system is maintained at a controlled processing environment at ambient pressure.
